(19) United States
(12) Patent Application Publication
(10) Pub. No.: US 2025/0380361 A1
(43) Pub. Date: Dec. 11, 2025

(54) CIRCUIT BOARDS, TEST SYSTEMS, AND TEST METHODS

(71) Applicant: Yangtze Memory Technologies Co., Ltd., Wuhan (CN)

(72) Inventors: Lumin He, Wuhan (CN); Jie Zhu, Wuhan (CN); Fan Wei, Wuhan (CN); Rongrong Wu, Wuhan (CN)

(21) Appl. No.: 18/824,596

(22) Filed: Sep. 4, 2024

(30) Foreign Application Priority Data
Jun. 6, 2024 (CN) 202410732720.0

(51) Int. Cl. H05K 1/11; G01R 31/28; G11C 29/10

(52) U.S. Cl. CPC H05K 1/115; G01R 31/2808; G11C 29/10; H05K 2201/09509; H05K 2201/10159

(57) ABSTRACT

The present disclosure provides a circuit board, a test system and a test method in the technical field of power consumption testing. The circuit board includes: a dielectric layer including at least one conductive via extending through the dielectric layer; first metal contacts disposed on a first side of the dielectric layer and second metal contacts disposed on a second side of the dielectric layer, wherein at least one of the first metal contacts is coupled with the second metal contacts through the conductive via; and at least one first metal pad located on the first side of the dielectric layer and at peripheries of the first metal contacts, wherein the first metal pad is coupled with at least one first metal contact through a first wiring in the dielectric layer.

### CROSS-REFERENCE TO RELATED APPLICATIONS

This application claims priority to and the benefit of Chinese Patent Application 202410732720.0, filed on Jun. 6, 2024, which is hereby incorporated by reference in its entirety.

### TECHNICAL FIELD

The present disclosure relates to the technical field of power consumption testing, and in example to circuit boards, test systems, and test methods.

### BACKGROUND

The power consumption measurement of an electronic device includes device-level power consumption measurement and system-level power consumption measurement. In the system-level power consumption measurement, since the device to be tested has been packaged into an electronic apparatus, pins of the device to be tested are blocked, which brings difficulties to the power consumption measurement of the device to be tested in the electronic apparatus.

### BRIEF DESCRIPTION OF THE DRAWINGS

In order to illustrate the technical solutions in the present disclosure more clearly, the drawings to be used in some examples of the present disclosure will be briefly introduced below. Apparently, the drawings in the following description are only drawings of some examples of the present disclosure. Those of ordinary skills in the art may also obtain other drawings according to these drawings. In addition, the drawings in the following description may be regarded as schematic diagrams, instead of limitations to actual size of product, flow of method, timing of signal, etc. involved in the examples of the present disclosure.

FIG. 1 is a schematic structural diagram of a printed circuit board according to some examples;

FIG. 2 is a schematic module diagram of an electronic apparatus according to some examples;

FIG. 3 is a schematic module diagram of a memory card according to some examples;

FIG. 4 is a schematic module diagram of a solid state drive according to some examples;

FIG. 5 is a schematic diagram I of a memory according to some examples;

FIG. 6 is a schematic diagram II of a memory according to some examples;

FIG. 7 is a schematic diagram I of a memory system according to some examples;

FIG. 8 is a schematic diagram II of a memory system according to some examples;

FIG. 9 is a schematic module diagram I of a test system according to some examples;

FIG. 10 is a schematic module diagram I of a circuit board according to some examples;

FIG. 11 is a schematic module diagram II of a test system according to some examples;

FIG. 12 is a schematic module diagram III of a test system according to some examples;

FIG. 13 is a schematic module diagram IV of a test system according to some examples;

FIG. 14 is a schematic module diagram V of a test system according to some examples;

FIG. 15 is a schematic module diagram I of a top view of a circuit board according to some examples;

FIG. 16 is a schematic module diagram II of a top view of a circuit board according to some examples;

FIG. 17 is a schematic module diagram III of a top view of a circuit board according to some examples;

FIG. 18 is a schematic module diagram IV of a top view of a circuit board according to some examples;

FIG. 19 is a schematic module diagram V of a top view of a circuit board according to some examples;

FIG. 20 is a schematic module diagram VI of a top view of a circuit board according to some examples;

FIG. 21 is a schematic module diagram VII of a top view of a circuit board according to some examples;

FIG. 22 is a schematic module diagram VI of a test system according to some examples;

FIG. 23 is a schematic module diagram VIII of a top view of a circuit board according to some examples;

FIG. 24 is a schematic module diagram VII of a test system according to some examples;

FIG. 25 is a schematic module diagram VIII of a test system according to some examples;

FIG. 26 is a schematic module diagram II of a circuit board according to some examples;

FIG. 27 is a schematic module diagram III of a circuit board according to some examples; and

FIG. 28 is a flow diagram of a test method according to some examples.

### DETAILED DESCRIPTION

The technical solutions in some examples of the present disclosure will be described below clearly and completely in conjunction with the drawings. Apparently, the examples described are only part of, but not all of, the examples of the present disclosure. All other examples obtained by those of ordinary skills in the art based on the examples provided by the present disclosure shall fall within the scope of protection of the present disclosure.

In the description of the present disclosure, it is to be understood that the terms “center”, “upper”, “lower”, “front”, “rear”, “left”, “right”, “vertical”, “horizontal”, “top”, “bottom”, “inner”, “outer”, etc. indicate orientations or position relationships that are based on the orientations or position relationships as shown in the drawings, and are only intended to facilitate description of the present disclosure and to simplify the description, instead of indicating or implying that a device or an element indicated must have a specific orientation or be constructed and operated in a specific orientation, and thus cannot be construed as limiting the present disclosure.

Unless otherwise specified in the context, throughout the specification and the claims, the term “comprise” or “include” is interpreted as an open and inclusive meaning, e.g., “including, but not limited to”. In the description of the specification, the terms “one example”, “some examples”, “an example”, or “in an example”, etc. are intended to indicate that particular features, structures, materials, or characteristics related to the example are included in at least one example of the present disclosure. The schematic representation of the above terms may not necessarily refer to the same example. Furthermore, these particular features, structures, materials, or characteristics may be included in one or more examples in any suitable manner.

In the following, the terms “first” and “second” are only for the purpose of description, and cannot be construed as indicating or implying relative importance or implicitly indicating the number of indicated technical features. Thus, features defined by “first” and “second” may explicitly or implicitly include one or more of such features. In the description of the examples of the present disclosure, “a plurality of” means two or more, unless otherwise stated.

In describing some examples, the expressions “coupled” and “connected” and derivatives thereof may be used. For example, the term “connected” may be used in the description of some examples to indicate that two or more components have a direct physical contact or an electrical contact with each other. For another example, the term “coupled” may be used in the description of some examples to indicate that two or more components have a direct physical or electrical contact. However, the term “coupled” may also mean that two or more components are not in direct contact with each other, but they may still cooperate or interact with each other. The examples disclosed herein are not necessarily limited to the content herein.

“At least one of A, B and C” and “at least one of A, B or C” have the same meaning, both including the following combinations of A, B and C: A alone, B along, C alone, a combination of A and B, a combination of A and C, a combination of B and C, and a combination of A, B and C.

The use of “suitable for” or “configured to” herein means open and inclusive language, and does not exclude an apparatus suitable for performing or configured to perform additional tasks or steps.

In addition, the use of “based on” means openness and inclusiveness, as processes, operations, calculations, or other actions “based on” one or more conditions or values may be based on an additional condition or exceeded value in practice.

First, some basic concepts involved in examples of the present application are explained and described.

A printed circuit board (PCB) is a carrier that is used to interconnect electronic components, and is fabricated by a series of electronic printing processes. The PCB generally includes an insulating substrate, conductive materials (such as copper foil), and holes or pads of components for soldering or insertion. These conductor patterns are formed by various processes such as etching, copper plating, lamination, etc., and are used for creating circuit paths to provide connection and signal transmission between circuits. The printed circuit board is one of core assemblies of an electronic apparatus, and its main function is to connect the electronic components such as a resistor, a capacitor, an inductor, a transistor, an integrated circuit, etc. into a complete circuitry, so as to achieve a predetermined function of the apparatus. The design of the PCB is generally performed according to the working principle and requirements of the circuitry, and the stability and reliability of the circuitry are ensured by accurate layout and routing. The PCB is classified into a variety of types, and may be classified into a single-sided PCB, a double-sided PCB, and a multi-layer PCB according to the number of layers.

The single-sided PCB, the double-sided PCB, and the multi-layer PCB are three main types of PCB, which differ in design and application.

The single-sided PCB is the simplest type of PCB, and only has conductive patterns (which is generally copper foil) on only one side of an insulating base. All electronic elements and connections are integrated on one side, and no conductive layer is on the other side. Due to its simplicity and low cost, the single-sided PCB is often used for simple circuits and prototype designs. Common applications include toys, simple power supplies, electronic door locks, etc.

The double-sided PCB has conductive patterns on both sides of an insulating base. The two layers of patterns may be electrically connected through metallized vias (e.g., through holes), so as to realize complexity of the circuit. Since routing may be on both sides, the double-sided PCB may provide higher routing density and more complex circuit design. The double-sided PCB is slightly more costly than the single-sided PCB, but is more powerful in functions and suitable for most electronic apparatuses.

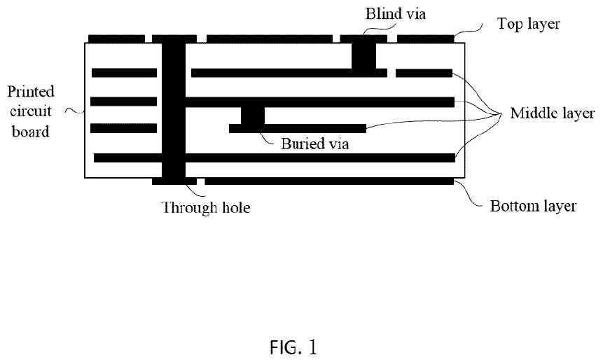

The multi-layer printed circuit board (multi-layer PCB), as shown in FIG. 1, is formed by alternately stacking a plurality of layers of conductive patterns (including a top layer, a plurality of middle layers, and a bottom layer) and insulation materials, and the layers are electrically connected through the metallized vias (e.g., through holes, buried vias, or blind vias) or inner layer connection circuits. The multi-layer PCB may include more levels of circuits, so as to realize a higher integration level and a more complex circuit design. The multi-layer PCB further includes a power supply layer and a ground layer, so as to improve electrical performance and reduce electromagnetic interference. The multi-layer PCB is relatively high in manufacturing cost but provides higher performance and reliability, and thus is suitable for high-end electronic apparatuses.

The metallized vias are generally classified into three categories, e.g., through holes, blind vias, and buried vias.

The blind via is located at surfaces of the top layer and bottom layer of the printed circuit board, has a certain depth, and is used to connect a surface layer circuit with an underlying inner layer circuit. The depth and aperture of the via generally do not exceed a certain ratio.

The buried via refers to a connection hole located at an inner layer of the printed circuit board, which does not extend to surfaces of the circuit board.

The through hole extends through the entire circuit board, and may be used to realize internal interconnection or used as a mounting positioning hole for components. Since it is easy to be implemented in process and has a low cost, the through hole is widely used for general printed circuit boards.

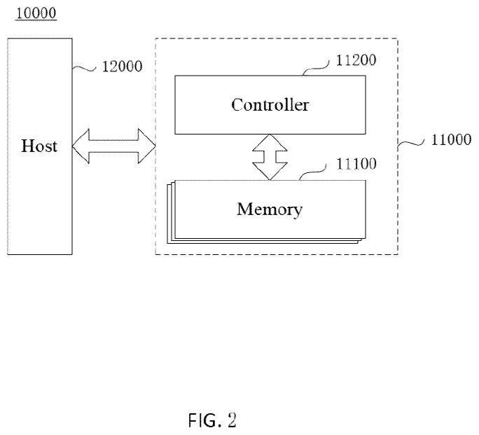

Examples of the present disclosure provide a memory system. The memory system may be applied to and packaged into different types of electronic apparatuses, such as a mobile phone (e.g., a cellphone), a desktop computer, a tablet computer, a notebook computer, a server, a vehicle apparatus, a gaming console, a printer, a positioning apparatus, a wearable apparatus (e.g., a smart watch, a smart bracelet, smart glasses, etc.), a smart sensor, a mobile power bank, a Virtual Reality (VR) apparatus, an Augmented Reality (AR) apparatus, or any other suitable electronic apparatuses having memories therein. As shown in FIG. 2, the electronic apparatus 10000 includes a memory system 11000 and a host 12000. The memory system 11000 includes one or more memories 11100 and a controller 11200. The controller 11200 is coupled with the memory 11100. The host 12000 may be a processor of the electronic apparatus. In an example, the processor may be a chip, which may be a field programmable gate array (FPGA), an application specific integrated circuit (ASIC), a System on Chip (SoC), a central processor unit (CPU), a network processor (NP), a digital signal processor (DSP), a micro controller unit (MCU), a programmable logic device (PLD), or an application processor (AP) or other integrated chips.

According to some implementations, the controller 11200 is coupled to the memory 11100 and the host 12000, and is configured to control the memory 11100. The controller 11200 may manage data stored in the memory 11100, and communicate with the host 12000. In some implementations, the controller 11200 is designed for operating in a low duty-cycle environment, such as a secure digital (SD) card, a compact flash (CF) card, a universal serial bus (USB) flash drive, or other media for use in electronic apparatuses, such as a personal computer, a digital camera, a mobile phone, etc. In some implementations, the controller 11200 is designed for operating in a high duty-cycle environment, such as a solid state drive (SSD) or an embedded multimedia card (eMMC) used as a data storage apparatus for mobile electronic apparatuses, such as a smartphone, a tablet computer, a personal computer, etc., and an enterprise memory cell array. The controller 11200 may be configured to manage data stored in the memory 11100, communicate with an external apparatus (e.g., the host 12000), and control operations of the memory 11100, such as read, erase, and program operations. In some examples, the controller 11200 may be further configured to manage various functions with respect to data stored or to be stored in the memory 11100, including, but not limited to, bad-block management, garbage collection, logical-to-physical address translation, wear leveling, etc. In some implementations, the controller 11200 is further configured to process error correction codes (ECCs) with respect to the data read from or written to the memory 11100. The controller 11200 may further perform any other suitable functions, for example, formatting the memory 11100. The controller 11200 may communicate with an external apparatus (e.g., the host 12000) according to a specific communication protocol.

For example, the controller 11200 may communicate with an external apparatus through at least one of various interface protocols, such as a USB protocol, a MultiMedia Card (MMC) protocol, a Peripheral Component Interconnect (PCI) protocol, a PCI Express (PCI-E) protocol, an Advanced Technology Attachment (ATA) protocol, a serial-ATA protocol, a parallel-ATA protocol, a Small Computer System Interface (SCSI) protocol, an Enhanced Small Device Interface (ESDI) protocol, an Integrated Drive Electronics (IDE) protocol, a Firewire protocol, etc.

Of course, the controller 11200 may further perform any other suitable functions, for example, formatting the memory 11100. For example, the controller 11200 may communicate with an external apparatus (e.g., the host) through at least one of various interface protocols.

It is to be noted that, the interface protocol includes at least one of a USB protocol, an MMC protocol, a Peripheral Component Interconnection (PCI) protocol, a PCI-Express (PCI-E) protocol, an Advanced Technology Attachment (ATA) protocol, a serial-ATA protocol, a parallel-ATA protocol, a Small Computer Small Interface (SCSI) protocol, an Enhanced Small Disk Interface (ESDI) protocol, an Integrated Drive Electronics (IDE) protocol, and a Firewire protocol.

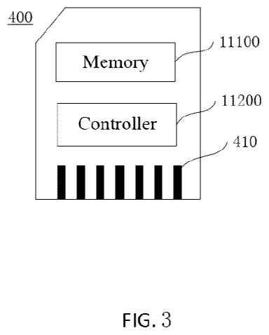

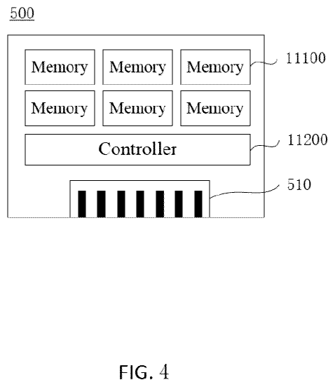

The controller 11200 and the one or more memories 11100 may be integrated into various types of memory systems, for example, be included in the same package, such as an Embedded Multimedia Card (eMMC), a Universal Flash Storage (UFS) package, an Embedded Multi Chip Package (eMCP), or a UFS-based Multichip Package (uMCP). The eMMC employs a unified MMC standard interface, and a high-density NAND and an MMC controller are packaged in a Ball Grid Array (BGA) package chip. The UFS is an advanced edition of the eMMC, and is also an array memory module consisting of a plurality of flash chips and a controller. The UFS compensates for the disadvantage that the eMMC only supports a half-duplex operation (reading and writing must be performed separately), and can realize a full-duplex operation, such that the performance is doubled. The eMCP is formed by carrying and packaging a volatile memory such as a Static Random-Access Memory (SRAM) or a Dynamic Random-Access Memory (DRAM) on the eMMC. In a specific implementation, the DRAM may be a Low Power Double Data Rate (LPDDR) SDRAM. The uMCP is formed by carrying and packaging a volatile memory (e.g., a SRAM or a DRAM) on a UFS, and has high performance and large capacity. In a specific implementation, the DRAM may be an LPDDR. That is to say, the memory system 11000 may be implemented and packaged into different types of end electronics. In one example shown in FIG. 3, the controller 11200 and the single memory 11100 may be integrated into a memory card 400. The memory card 400 may include a Personal Computer Memory Card International Association (PCMCIA) PC card, a CF card, a smart media (SM) card, a memory stick, a multimedia card (MMC, RS-MMC, MMCmicro), an SD card (SD, miniSD, microSD, SDHC), a UFS, etc. The memory card 400 may further include a memory card connector 410 coupling the memory card 400 with a host (e.g., the host 12000 in FIG. 2). In another example shown in FIG. 4, the controller 11200 and the plurality of memories 11100 may be integrated into an SSD 500. The SSD 500 may further include an SSD connector 410 coupling the SSD 500 with a host (e.g., the host 12000 in FIG. 2). In some implementations, the storage capacity and/or operation speed of the SSD 500 are greater than those of the memory card 400.

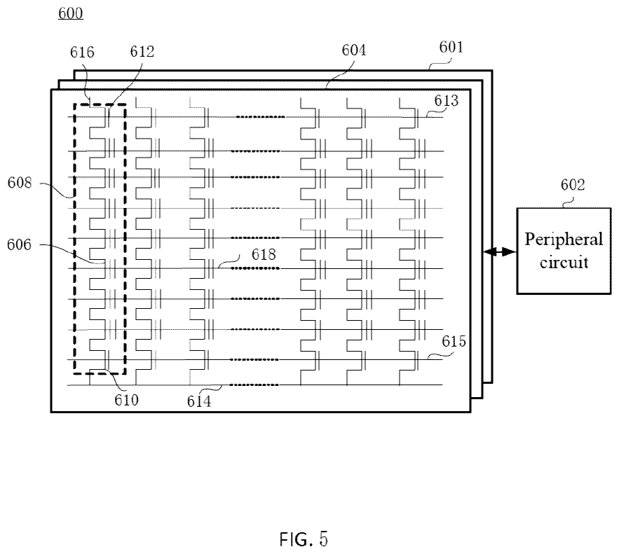

FIG. 5 shows a schematic circuit diagram of an example memory 600 including a peripheral circuit 602 according to some aspects of the present disclosure. The memory 600 may be an example of the memory 11100 in FIG. 2. The memory 600 may include a memory cell array 601 and a peripheral circuit 602 coupled to the memory cell array 601. The memory cell array 601 may be a NAND flash memory cell array, where memory cells 606 are provided in the form of an array of NAND memory strings 608 extending vertically on a substrate (not shown). In some implementations, each NAND memory string 608 includes the plurality of memory cells 606 coupled in series and stacked vertically. Each memory cell 606 can maintain a continuous analog value, such as voltage or charge, which depends on the number of electrons trapped in a region of the memory cell 606. Each memory cell 606 may be either a floating gate type memory cell including a floating gate transistor, or a charge trapping type memory cell including a charge trapping transistor.

In some implementations, each memory cell 606 is a single-level cell (SLC) that has two possible storage states (levels) and thus can store one bit of data. For example, a first storage state “0” may correspond to a threshold voltage in a first range, and a second storage state “1” may correspond to a threshold voltage in a second range. In some implementations, each memory cell 606 is an xLC that can store more than one bit of data in more than four storage states (levels). For example, the xLC can store two bits (Multi-Level Cell (MLC)) per cell, store three bits (Triple-Level Cell (TLC)) per cell, or store four bits (Quad-Level Cell (QLC)) per cell. Each xLC may be programmed to assume a certain range of possible nominal storage values (e.g., 2N segments of N-bit data, such as a Gray code). In one example, the MLC may be programmed to assume one of three possible program levels from an erased state by writing one of three possible nominal storage values to a cell. A fourth nominal storage value may be used for the erased state.

As shown in FIG. 5, each NAND memory string 608 may further include a source select gate (SSG) transistor 610 at its source terminal and a drain select gate (DSG) transistor 612 at its drain terminal. The SSG transistor 610 and the DSG transistor 612 may be configured to activate a selected NAND memory string 608 (a column of an array) during read and program operations. In some implementations, sources of the NAND memory strings 608 in the same block 604 are coupled through the same source line (SL) 614 (e.g., a common SL). In other words, according to some implementations, all the NAND memory strings 608 in the same block 604 have an array common source (ACS). According to some implementations, the drain of each NAND memory string 608 is coupled to a corresponding bit line 616, and data can be read or written from the corresponding bit line 616 via an output bus (not shown). In some implementations, each NAND memory string 608 is configured to be selected or unselected by applying a select voltage or an unselect voltage to a gate of the corresponding DSG transistor 612 via one or more DSG lines 613 and/or by applying a select voltage or an unselect voltage to a gate of the corresponding SSG transistor 610 via one or more SSG lines 615.

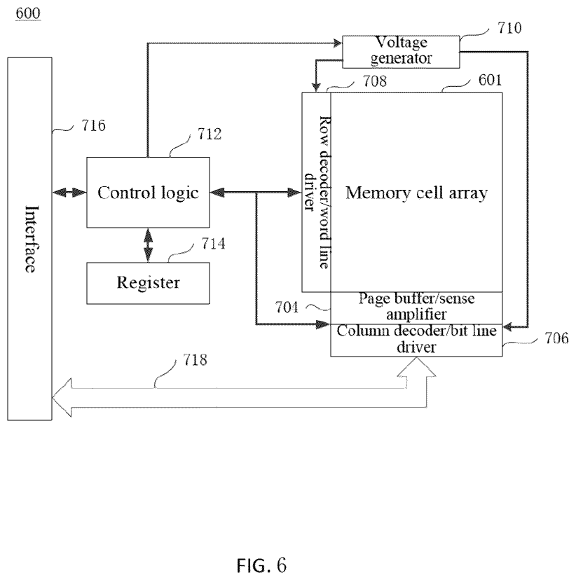

As shown in FIG. 5, the NAND memory strings 608 may be organized into a plurality of blocks 604, and each of the blocks 604 may have a common source line 614, e.g., coupled to the ACS. In some implementations, each block 604 is a basic data unit for an erase operation, e.g., all of the memory cells 606 on the same block 604 are erased at the same time. In order to erase the memory cells 606 in a selected block 604, the source line 614 coupled to the selected block 604 as well as unselected blocks 604 that are in the same plane as the selected block 604 may be biased with an erase voltage (Vers) such as a high positive bias voltage (e.g., 20 V or higher). The memory cells 606 of adjacent ones of the NAND memory strings 608 may be coupled through a word line (WL) 618 that selects which row of memory cells 606 is affected by the read and program operations. The peripheral circuit 602 may be coupled to the memory cell array 601 through the Bit Line (BL) 616, the word line 618, the source line 614, the SSG line 615, and the DSG line 613. The peripheral circuit 602 may include any suitable analog, digital, and hybrid signal circuits for facilitating operations of the memory cell array 601 by applying and sensing voltage signals and/or current signals to and from each target memory cell 606 via the bit line 616, the word line 618, the source line 614, the SSG line 615, and the DSG line 613. The peripheral circuit 602 may include various types of peripheral circuits formed using a metal-oxide-semiconductor (MOS) technology. For example, FIG. 6 shows some example peripheral circuits, including a page buffer/sense amplifier 704, a column decoder/bit line driver 706, a row decoder/word line driver 708, a voltage generator 710, a control logic 712, a register 714, an interface (I/F) 716, and a data bus 718. It is to be understood that, additional peripheral circuits not shown in FIG. 6 may be also included as well.

The page buffer/sense amplifier 704 may be configured to read and program (write) data from and to the memory cell array 601 according to a control signal from the control logic 712. In an example, the page buffer/sense amplifier 704 may perform a program verify operation to ensure that data has been properly programmed into the memory cells 606 coupled to the selected word line 618. In another example, during the read operation, the page buffer/sense amplifier 704 may also sense low power signals from the bit line 616 that represent data bits stored in the memory cells 606, and amplify a small voltage swing to a recognizable logic level. As described in detail below and consistent with the scope of the present disclosure, in the program operation, the page buffer/sense amplifier 704 may include a storage module (e.g., a latch, a cache, a register, etc.), and is configured to temporarily store a segment of N-bit data (e.g., in the form of a Gray code) received from the data bus 718, and provide the segment of N-bit data to the corresponding target memory cell 606 through the corresponding bit line 616 in each of the plurality of program operations using a 2^{N}-2^{N} solution.

The column decoder/bit line driver 706 may be configured to be controlled by the control logic 712, and select one or more NAND memory strings 608 by applying a bit line voltage generated by the voltage generator 710. The row decoder/word line driver 708 may be configured to be controlled by the control logic 712, select/unselect the blocks 604 of the memory cell array 601, and select/unselect the word lines 618 of the blocks 604. The row decoder/word line driver 708 may be further configured to drive the word lines 618 using a word line voltage generated by the voltage generator 710. In some implementations, the row decoder/word line driver 708 may also select/unselect and drive the SSG line 615 and the DSG line 613. The voltage generator 710 may be configured to be controlled by the control logic 712, and generate the word line voltage (such as, read voltage, program voltage, pass voltage, local voltage, verify voltage, etc.), the bit line voltage, and a source line voltage to be supplied to the memory cell array 601.

The control logic 712 may be coupled to each peripheral circuit described above and configured to control operations of each peripheral circuit. The register 714 may be coupled to the control logic 712 and include a state register, a command register, and an address register, so as to store state information, command Operation Codes (OP), and command addresses for controlling the operations of each peripheral circuit. The interface 716 may be coupled to the control logic 712, and serve as a control buffer to buffer and forward control commands received from a host (e.g., the host 12000 in FIG. 2) to the control logic 712 and state information received from the control logic 712 to the host. The interface 716 may be also coupled to the column decoder/bit line driver 706 via the data bus 718 and serve as a data input/output (I/O) interface and a data buffer to buffer and forward the data to and from the memory cell array 601.

In stages of design, manufacturing, application verification, etc. of a memory system, in order to evaluate the performance of the memory system, by measuring power consumption performance of the memory system in different working states (e.g., performing power consumption measurement on the memory system), the high power consumption working mode or operation can be recognized, such that targeted optimization may be performed. For example, in the design stage of the memory system, the rationality and feasibility of the design solution may be verified through a power consumption test. This helps a designer to find out and address potential power consumption problems at an early stage, so as to optimize the design of the memory system and improve energy efficiency. After manufacturing is completed, performing power consumption measurement on the memory system may ensure the memory system meets design specifications, and guarantee the reliability of the memory system during use as well. This helps a manufacturer to guarantee the product quality, and reduce the defective product rate. In the application verification stage, for example, the memory system is packaged into an electronic apparatus such as a cellphone, a table computer, a mobile terminal, etc., and the performance of the memory system in a practical application may be evaluated through power consumption measurement. This helps to find out the power consumption problems of the memory system in different application scenarios, and provide reference for subsequent optimization.

In the design and manufacturing stages of the memory system, the memory system is not packaged in the electronic apparatus yet, and only the performance of the memory system device itself is tested, which belongs to a device-level power consumption measurement. A device-level power consumption measurement solution can meet a test requirement generally through a customized test board. In the application verification stage of the memory system, for example, the memory system is packaged into a mobile phone (e.g., a cellphone), a desktop computer, a tablet computer, a notebook computer, a server, a vehicle apparatus, a gaming console, a printer, a positioning apparatus, a wearable apparatus (e.g., a smart watch, a smart bracelet, smart glasses, etc.), a smart sensor, a mobile power bank, a Virtual Reality (VR) apparatus, an Augmented Reality (AR) apparatus, or any other suitable electronic apparatuses having memories therein, the power consumption measurement of the memory system belongs to a system-level device power consumption measurement. For the system-level device power consumption measurement, examples of the present disclosure provide two methods: the first method is to extend wirings and externally connect with a power supply, e.g., wirings are extended and a power supply apparatus is externally connected for power consumption measurement. The second method is to use a probe to directly perform measurement on power supply wiring, for example, a current probe is directly clamped on the power supply wiring, and then senses the current in the wiring for measurement. Both methods generally need modifications to perform measurement.

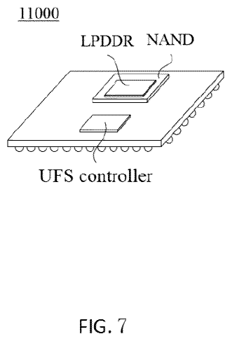

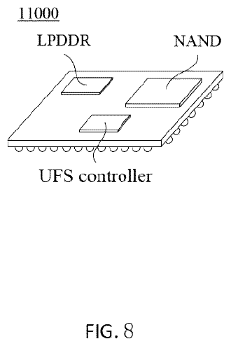

However, the two system-level device power consumption measurement methods provided by the examples of the present disclosure above also have limitations in some scenarios, which is illustrated by taking the electronic apparatus 10000 as a cellphone as an example. Based on high requirements of a cellphone for the storage capacity and performance, the memory system 11000 may, but is not limited to, select a uMCP chip. In this example, by taking the memory system 11000 selecting the uMCP as an example, the uMCP is formed by carrying and packaging a volatile memory (e.g., the SRAM or DRAM) on the UFS, and has high performance and large capacity. In a specific implementation, as shown in FIGS. 7 or 8, the memory system 11000 includes the volatile memory and the UFS. The volatile memory is coupled with the UFS. The UFS is a memory device that packages a memory (such as a NAND) and a UFS controller together. The volatile memory may be an LPDDR that is a special dynamic random-access memory DRAM and is mainly used for mobile apparatuses such as a cellphone, a tablet computer, a portable computer, etc. Compared to the DRAM, the LPDDR has lower power consumption and higher bandwidth, and has a faster response speed at the same time. When system-level device power consumption measurement is performed on the uMCP chip on a cellphone, there are three main challenges.

First, cellphone has a very high density of electronic components, such that it is difficult to make modifications directly on a host for power consumption measurement connections. Such modifications are complex in operation and has high risks, and a tiny error may damage the electronic apparatus, which further increases the uncertainty of the power consumption measurement.

Secondly, the high-speed nature of LPDDR signal makes it extremely sensitive to any extension or modification for the signal wiring. Since, in a high-speed circuit, the wavelength of signal is no longer far greater than the circuit size, but is equivalent to or even smaller than it, voltages of the signal at various positions of a wire can no longer be regarded as equal. This means that a waveform measured at a starting point or middle point of the wire cannot represent a waveform received at an end point of the wire. Thus, the high-speed signal should be measured as close as possible to the receiving end. Changes due to any extension or modification often result in signal attenuation, distortion and delay, thus seriously affecting signal integrity. Since the accuracy of the measurement result directly depends on the signal integrity, extension and external connection solution is no longer applicable in this scenario, as it cannot provide accurate and reliable power consumption measurement data. Meanwhile, for some scenarios that a test apparatus (such as an oscilloscope) needs to be connected in series to a circuit for measurement, applying modification to the wiring is even more difficult. Thus, the extension and external connection solution fails in these scenarios.

Furthermore, the special package type of the uMCP chip has also brought problems. The uMCP package has a package type of Ball Grid Array (BGA). BGA package is a high density surface assembly packaging technology. In this packaging technology, ball-shaped pins are used to connect an integrated circuit (IC) and a host or other circuit boards, and the pins are all ball-shaped and arranged in a grid (which may be referred to as a ball map) at the bottom of the package, thus being named as the ball grid array package. The uMCP chip has two standard package types, both of which may have an overall size of 13*11.5 mm. When the uMCP chips of those package types are integrated into the electronic apparatus 10000, they are coupled with the host 12000 through the ball-shaped pins. All the pins are located directly below (not on sides of) the chips such that the pins of the uMCP chips are blocked. Therefore, it is almost impossible to perform direct measurement on the BGA pins by using a probe of a current detection apparatus or by using a probe of an oscilloscope apparatus. Thus, this packaging method significantly increases the difficulty of power consumption measurement.

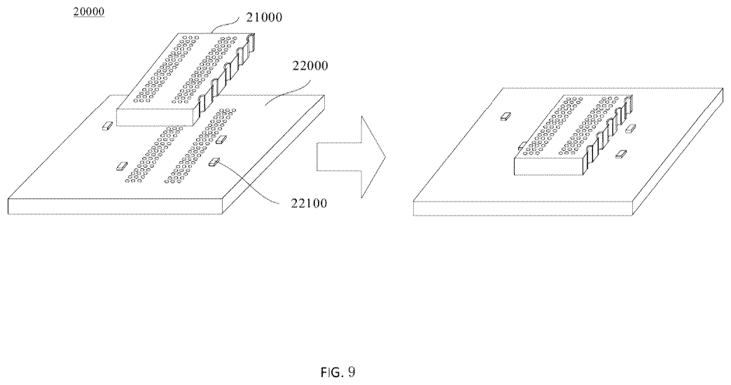

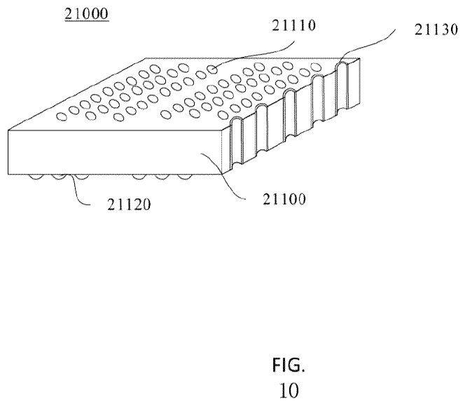

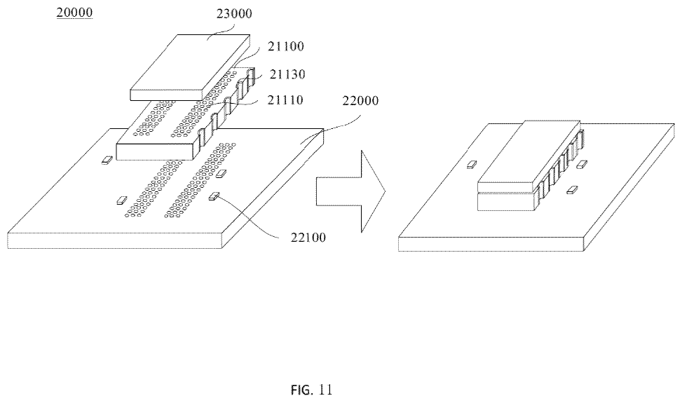

Examples of the present disclosure provide a test system. As shown in FIG. 9, the test system 20000 may include a circuit board 21000 and a host 22000 (which may be the host 12000 in FIG. 2) that are stacked and coupled sequentially. The circuit board 21000 is used to couple (or connect) the host 22000 to a memory system to be tested (which may be the memory system 11000 in FIG. 2). The host 22000 includes an electronic device 22100 (e.g., a resistance-capacitance device, etc.). The test system 20000 may further include a test apparatus (e.g., a waveform detection apparatus and a current detection apparatus, not shown in the figure). As shown in FIG. 10, the circuit board 21000 includes a dielectric layer 21100, where the dielectric layer 21100 includes at least one conductive via (which is not shown in FIG. 10 and may refer to a metal conductive via shown in FIG. 1) extending through the dielectric layer 21100. The circuit board further includes: a plurality of first metal contacts 21110 (corresponding to pins of the memory system to be tested and having the same package type) disposed on a first side (an upper surface or lower surface of the circuit board 21000) of the dielectric layer 21100, and a plurality of second metal contacts 21120 (corresponding to the pins of the memory system to be tested and having the same package type) disposed on a second side (the upper surface or lower surface of the circuit board 21000, the first side being different from the second side) of the dielectric layer 21100. At least one of the plurality of first metal contacts 21110 is coupled with the second metal contacts 21120 through the conductive via. The first side of the dielectric layer 21100 further includes at least one first metal pad 21130 disposed at peripheries of the plurality of first metal contacts 21110, and the first metal pad 21130 is coupled with the at least one first metal contact 21110 through a first wiring (not shown in the figure) in the dielectric layer 21100. As shown in FIG. 11, the plurality of first metal contacts 21110 on the first side of the dielectric layer 21100 are configured to be coupled with the memory system to be tested 23000 (which may be the memory system 11000 in FIG. 2), and the plurality of second metal contacts 21120 on the second side of the dielectric layer 21100 are configured to be coupled with the host 22000. When the test system 20000 is used to perform system-level device power consumption measurement on the memory system to be tested 23000, the memory system to be tested 23000 is coupled with a first side of the circuit board 21000. A signal to be tested (e.g., a current signal or a voltage signal) on the memory system to be tested 23000 is led out to the first metal pad 21130 pre-disposed on the circuit board 21000 through a corresponding metal contact on the circuit board 21000. This may be also understood as equivalent to adding one circuit board 21000 between the memory system 11000 and the host 12000 in the electronic apparatus 10000 shown in FIG. 1 for direct connection between the memory system 11000 and the host 12000. A test signal of the memory system 11000 is led out to the first metal pad 21130 on the circuit board 21000 as a signal test point, so as to acquire the signal to be tested through the first metal pad 21130, and the power consumption of the memory system to be tested 23000 is measured, thereby avoiding extension of external connected wirings and the difficulties in direct measurement using a current probe caused by the blocked pins.

In the solutions shown in FIGS. 9, 10, and 11, the sizes of the first side and the second side of the dielectric layer 21100 are designed to be consistent with a package size of the memory system to be tested 23000. Likewise, the first metal contacts 21110 on the first side of the dielectric layer 21100 and the second metal contacts 21120 on the second side not only match the pins (in BGA package) of the memory system to be tested 23000 in the package type, but also have the same ball map as that of the memory system to be tested 23000. However, due to the limited space on the host 22000, resistors and capacitors or other electronic devices 22100 are often arranged around a mounting position reserved for the memory system to be tested 23000, such that the circuit board 21000 is unable to be directly attached to the host 22000. In order to avoid space conflict between the circuit board 21000 and the resistors and capacitors and other devices, ensure that the circuit board 21000 can be smoothly mounted in a designated position of the memory system to be tested 23000 on the host 22000, and avoid interference with the neighboring electronic devices 22100, as shown in FIGS. 9, 10, and 11, the first metal pads 21130 may be disposed on a side (one or more sides) of the circuit board 21000, so as to achieve the purpose of saving space, and avoid space conflict between the circuit board 21000 and the neighboring electronic devices 22100 caused by the extension of the circuit board 21000 for disposing the first metal pads 21130. These first metal pads 21130 inside the circuit board 21000 are connected with the metal contacts corresponding to the signal to be tested on the first side of the dielectric layer 21100 by wirings, such that it is possible to measure a signal of the memory system to be tested 23000 through the first metal pads 21130. Meanwhile, these regularly disposed external measurement points (the first metal pads 21130) not only facilitate access to test apparatus probes, but also significantly improve convenience of testing.

However, in some scenarios, the first metal pads 21130 disposed on the side of the circuit board 21000 may result in a risk of short circuit due to insufficient safety distance from pins of other electronic devices 22100 on the host 22000. It is also possible that the safety distance between the first metal pad 21130 on the side and the first metal contact 21110 and the second metal contact 21120 cannot be guaranteed due to the purpose of saving space. This potential safety hazard may not only result in inaccurate test data, but may also damage the memory system to be tested 23000. Therefore, during design and mounting processes, it must be ensured that there is a sufficient safety distance between these metal pads and other electronic devices 22100, so as to avoid unnecessary losses.

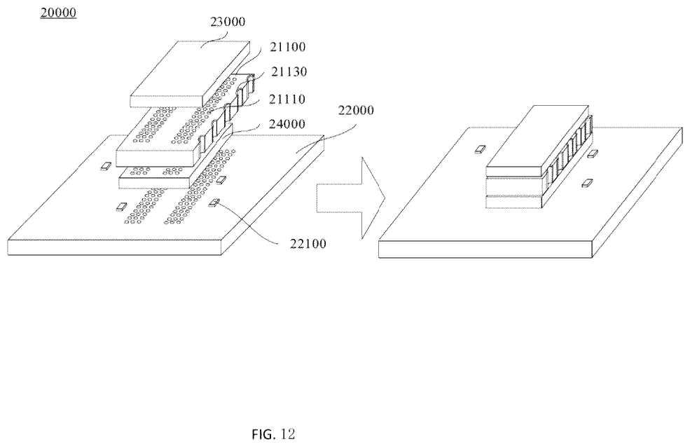

Thus, in order to avoid space conflict between the circuit board 21000 and the resistors and capacitors and other devices, and to avoid safety risks that may be caused by disposing the metal pads on the side of the circuit board 21000, in some examples, as shown in FIG. 12, the test system 20000 further includes an intermediate plate 24000 disposed between the host 22000 and the circuit board 21000. The circuit board 21000, the intermediate plate 24000, and the host 22000 are stacked and coupled sequentially, e.g., the intermediate plate 24000 may be additionally disposed between the circuit board 21000 and the host 22000. The structure of the intermediate plate 24000 is similar to that of the circuit board 21000, in which signal communication upwards and downwards can be achieved, except that there is no lead-out measurement point (a metal pad for measurement). In this example, the size of the circuit board 21000 may be greater than or equal to the size of the memory system to be tested 23000.

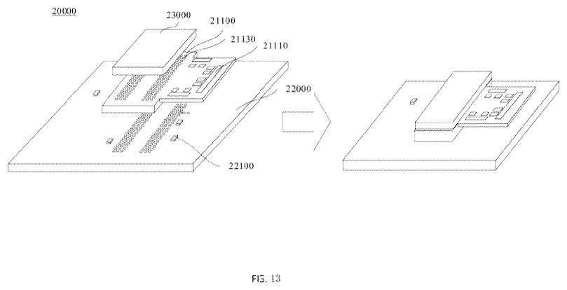

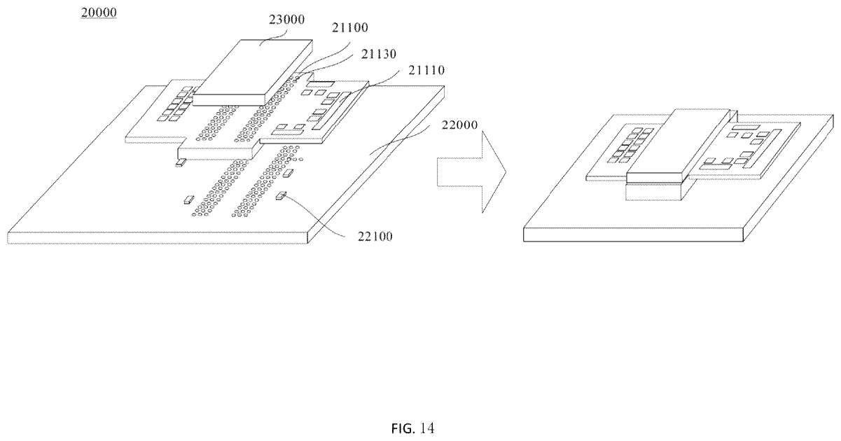

In some examples, the dielectric layer 21100 further includes recesses located on the second side of the dielectric layer 21100 and at the peripheries of the plurality of second metal contacts 21120. That is, on the second side of the dielectric layer 21100, the corresponding thickness of the dielectric layer 21100 provided with the plurality of second metal contacts 21120 is greater than the corresponding thickness of the dielectric layer 21100 not provided with the plurality of second metal contacts 21120. As shown in FIGS. 13 and 14, the circuit board 21000 may be processed into an F shape. The first side of the dielectric layer 21100 includes an extending portion that extends in at least one direction of a region for mounting the memory system to be tested 23000, and the first metal pad 21130 is disposed at the extending portion. The size of the second side of the dielectric layer 21100 remains the same as the size of the memory system to be tested 23000. If space permits, the size of the second side of the dielectric layer 21100 may be greater than the size of the memory system to be tested 23000, which is not limited herein.

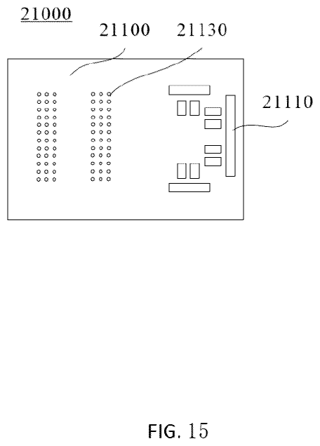

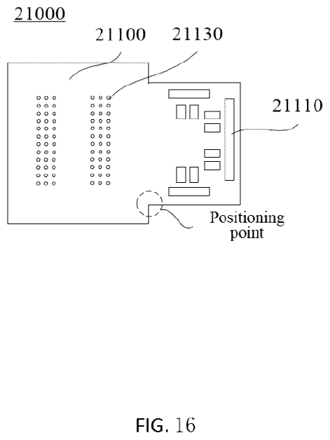

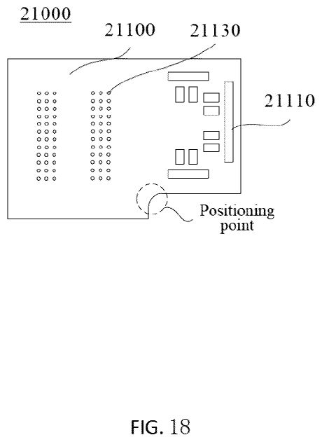

In an example, as shown in FIG. 13, in order to extend in one direction of the region for mounting the memory system to be tested 23000 (for example, the circuit board 21000 with the size of 13*11.5 mm+11*X mm is formed on the first side of the dielectric layer 21100, where 11 represents the width of the extending portion, and X represents the length of the extending portion), the specific size may be designed according to actual requirements. Top views of some possible circuit boards 21000 in the test system 20000 shown in FIG. 13 are shown in FIGS. 15, 16, or 17. Positioning points are included in FIGS. 15 or 16, and are used for positioning when mounting the memory system to be tested 23000 on the circuit board 21000, so as to accurately mount the memory system to be tested 23000 on the circuit board 21000. In some examples, edge rounding may be also performed on the positioning points, as shown in FIG. 18.

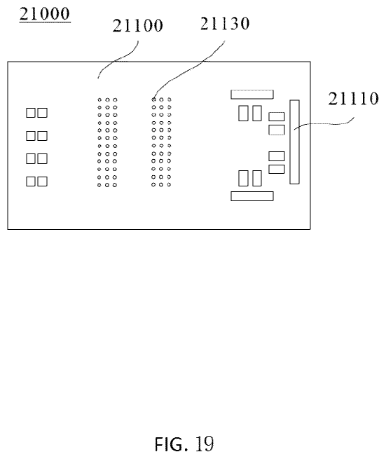

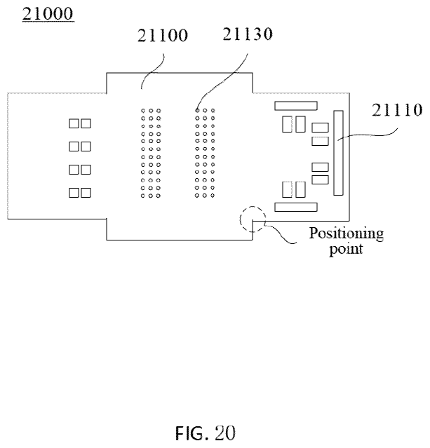

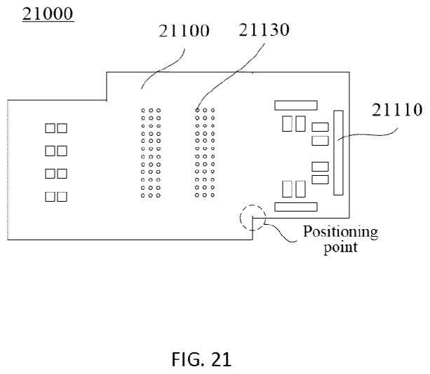

In an example, as shown in FIG. 14, in order to extend in two opposite directions of the region for mounting the memory system to be tested 23000, the specific size may be designed according to actual requirements. Top views of some possible circuit boards 21000 in the test system 20000 shown in FIG. 14 are shown in FIGS. 19, 20, or 21. Positioning points are included in FIGS. 20 or 21, and are used for positioning when mounting the memory system to be tested 23000 on the circuit board 21000, so as to accurately mount the memory system to be tested 23000 on the circuit board 21000. In some examples, edge rounding may be also performed on the positioning points. Of course, the first side of the dielectric layer 21100 may also extend in three directions of the region for mounting the memory system to be tested 23000, which is not limited herein.

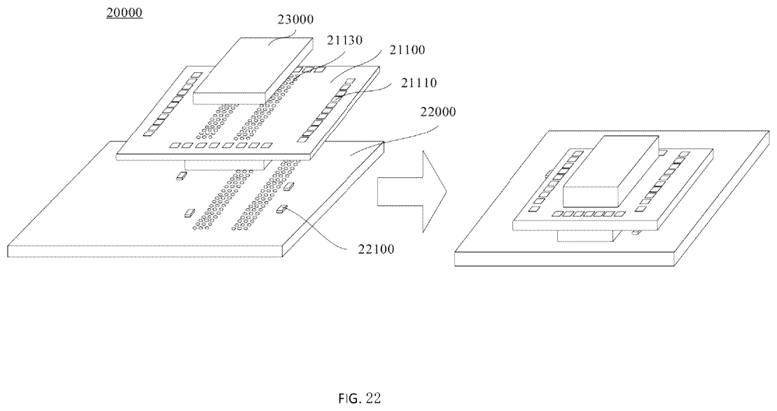

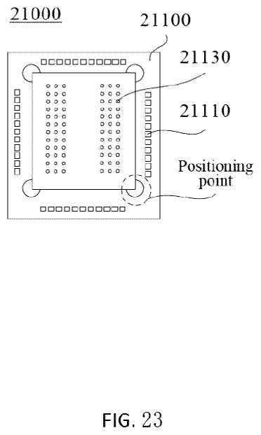

In an example, as shown in FIG. 22, in order to extend around the region for mounting the memory system to be tested 23000, e.g., the circuit board 21000 may be processed into a T shape, the first side of the dielectric layer 21100 extends around the region for mounting the memory system to be tested 23000 (for example, a circuit board 21000 with a size of 18*15 mm is formed on the first side of the dielectric layer 21100), and the specific size may be designed according to actual requirements. A top view of some possible circuit boards 21000 in the test system 20000 shown in FIG. 22 is shown in FIG. 23. The size of the second side of the dielectric layer 21100 remains the same as the size of the memory system to be tested 23000. Of course, if space permits, the size of the second side of the dielectric layer 21100 may be greater than the size of the memory system to be tested 23000, which is not limited herein. Positioning points are included in FIG. 23, and are used for positioning when mounting the memory system to be tested 23000 on the circuit board 21000, so as to accurately mount the memory system to be tested 23000 on the circuit board 21000.

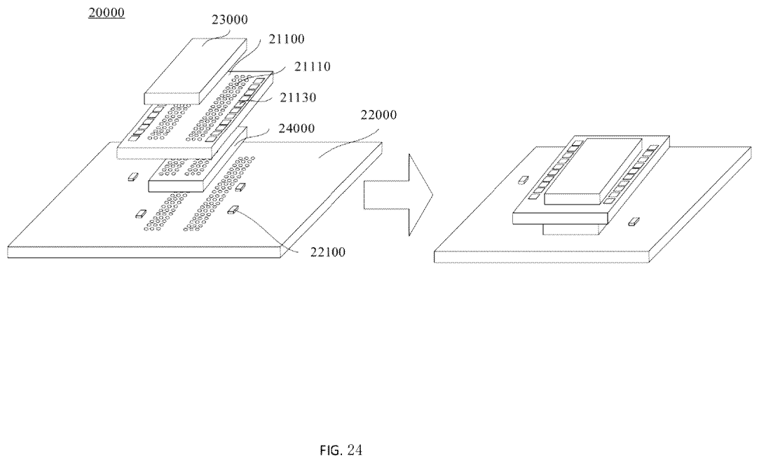

It is to be noted that, in implementations shown in FIGS. 12, 13, 14, 15, 16, 17, 18, 19, 20, 21, 22, and 23, the metal pads may be disposed on the lateral side of the circuit board 21000, or may be also disposed on the front side of the circuit board 21000, which is not limited herein. But the metal pads may be disposed at the peripheries of the metal contacts. In an implementation corresponding to FIG. 12, the circuit board 21000 may be also designed as shown in FIG. 24, and the metal pads are disposed on the front side of the extending portion of the circuit board 21000.

In the implementations shown in FIGS. 12, 13, 14, 15, 16, 17, 18, 19, 20, 21, 22, and 23, first, by introducing the intermediate plate 24000 or processing the circuit board 21000 into an F shape or T shape, extra space is provided for the circuit board, thus conflicts with other components are effectively avoided, thereby reducing safety risks. This design not only avoids short-circuit risks that may be caused by directly disposing the metal pads on sides of the circuit board, but also ensures a reasonable layout and mounting of various assemblies of the system, thus the integration level and reliability of the system are significantly improved. Secondly, this design extends the size of the circuit board 21000, such that metal pads may be disposed at the extending portion of the circuit board. In this way, on the one hand, more first metal pads 21130 may be led out as test points, so as to acquire more complete test information of the memory system to be tested 23000. This improvement can achieve comprehensive and accurate evaluation of the performance of the memory system to be tested, which provides strong support for system optimization. On the other hand, a safety distance can be also guaranteed between the first metal pad 21130 and the first metal contact 21110 and the second metal contact 21120. Furthermore, the design of the intermediate plate 24000 and the F-shaped or T-shaped circuit board not only solves the problem of space conflict, but also improves the maintainability and testability of the system. The intermediate plate 24000 may be used as a test interface to facilitate signal testing, thereby improving the test efficiency. The F-shaped or T-shaped circuit board provides more mounting and fixing options, such that the system is more flexible and easy to maintain. These improvements reduce the maintenance cost, and extend the service life of the system. In terms of cost effectiveness, no excessive new apparatuses and materials may be introduced due to the innovative design of the intermediate plate 24000 and the F-shaped or T-shaped circuit board, such that the production cost is reduced. Meanwhile, since the performance and stability of the system are improved and the extra cost caused by failures and maintenance is reduced, the cost effectiveness of the system is further improved. To sum up, through the design of adding the intermediate plate 24000 and processing the circuit board 21000 into the F shape or T shape, space conflict between the circuit board 21000 and the resistors and capacitors and other devices and safety risks that may be caused by disposing the metal pads on sides of the circuit board 21000 are avoided, such that the safety, reliability, testability, and cost effectiveness of the system are significantly improved.

In order to ensure that the introduction of the circuit board 21000 does not affect a connection relationship between the host 22000 and the memory system to be tested 23000, and the circuit board 21000 can meet different test requirements or application scenarios, the plurality of first metal contacts 21110 and the plurality of second metal contacts 21120 are coupled by two methods. The first method is that all the first metal contacts 21110 on the first side are correspondingly connected with all the second metal contacts 21120 on the second side through vias. The second method is that some of the first metal contacts 21110 on the first side are correspondingly connected with some of the second metal contacts 21120 on the second side through the vias, and other uncoupled first metal contacts 21110 and second metal contacts 21120 may be coupled according to actual test requirements by external wirings or serially connecting with a test apparatus, etc. If the metal contacts for supplying power are not coupled, an external power supply may be used to supply power to ensure that the memory system to be tested 23000 operates normally on the host 22000. The two method are described respectively as follows:

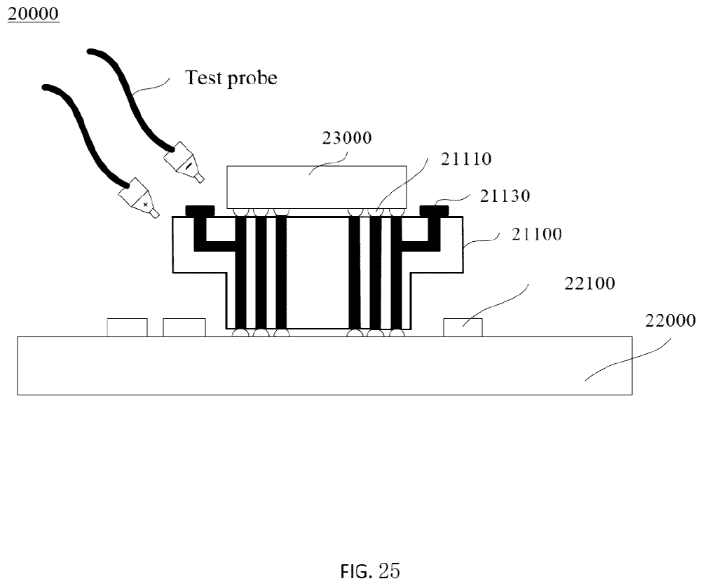

In some implementations, all the first metal contacts 21110 on the first side are correspondingly connected with all the second metal contacts 21120 on the second side through the vias. Taking the test system 20000 shown in FIG. 22 as an example, as shown in FIG. 25, the circuit board 21000 of this coupling method usually only requires a double-sided circuit board, and all test signals may be led out to the first metal contacts 21110 on the first side of the circuit board 21000. The memory system to be tested 23000 is solely powered by the host 22000. The test apparatus may obtain respective test data by coupling a test probe to a respective test point (metal pad). However, this coupling method is difficult to meet some test requirements, for example, the test apparatus may be serially connected between the memory system to be tested 23000 and the host 22000, or the memory system to be tested 23000 may be powered separately for testing.

In order to ensure the circuit board 21000 can meet different test requirements of the memory system to be tested 23000, so as to achieve the flexibility of system-level device power consumption measurement through the circuit board 21000, in some implementations, some of the first metal contacts 21110 on the first side are correspondingly connected with some of the second metal contacts 21120 on the second side through the vias. For example, in a ball map on the second side of the dielectric layer 21100 in the circuit board 21000 and a ball map on the first side of the dielectric layer 21100, in addition to cutting off a power supply signal, other signal points maintain a direct connection between upper and lower layers, such that the integrity of signal transmission is guaranteed. The power supply between the host 22000 and the memory system to be tested 23000 is cut off from the middle, so as to be applicable in different test scenarios. Internal/external power supply modes may be flexibly switched, or current test wirings are added, such that the circuit board 21000 is applicable in different test scenarios.

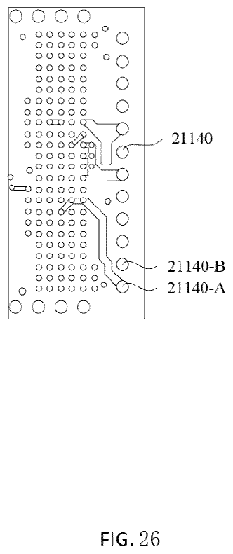

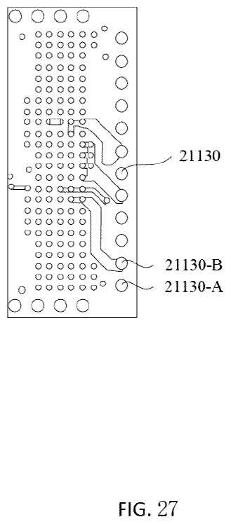

In some examples, taking uMCP297 as an example, FIG. 26 shows the second side of the dielectric layer 21100 of the circuit board 21000 of a UFS portion in a uMCP chip, the second side of the dielectric layer 21100 further includes at least one second metal pad 21140 disposed at the peripheries of the plurality of second metal contacts 21120, and the second metal pads 21140 are coupled with the plurality of second metal contacts 21120 through a second wiring in the dielectric layer 21100. FIG. 27 shows the first side of the dielectric layer 21100 of the circuit board 21000 of the UFS portion in the uMCP chip. Power supply signal points of the UFS portion include VCC, VCCQ, and VCCQ2. Taking the VCCQ as an example, all VCCQ signal points of the second side of the dielectric layer 21100 are pulled out and jointly connected to the position of a second metal pad 21140-A (including metal holes), defined as VCCQ_Host, which is directly connected to a VCCQ signal on the host 22000, a second metal pad 21140-B is placed beside and is defined as VCCQ_Device, which is connected back to a first metal pad 21130-A of a power supply layer on the first side of the dielectric layer 21100 through a via, and the VCCQ of the power supply layer on the first side of the dielectric layer 21100 is coupled with a first metal pad 21130-B. Since there is no wiring connection between the first metal pad 21130-A and the first metal pad 21130-B in the circuit board 21000, during actual power consumption measurement, the VCCQ_Device and the VCCQ_Host may be short-circuited according to the electronic apparatus, and it is powered by the host or may be also directly connected to an external power supply for use.

In some examples, in a uMCP297 package, power supply signal points of an LPDDR portion include VDD, VDD1, VDD2H, and VDD2L. A plurality of point positions with the same designation on the same layer may be connected to the same metal pad and then connected back (connecting back here does not mean that the two metal pads are necessarily coupled, but may be also disconnected, and the coupling condition is merely provided during design) to various corresponding point positions in another layer through another metal pad, and then the two metal pads are short-circuited or powered externally, so as to ensure that the uMCP chip can operate normally. Specific implementations are similar with the implementations shown in FIGS. 26 and 27.

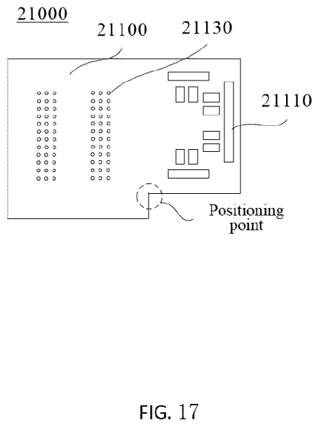

In some implementations, as an example, the test system shown in FIG. 17 is designed and fabricated to perform system-level device power consumption measurement on a uMCP297 chip, a power supply signal (as shown in FIGS. 26 and 27) such as UFS_VDDIQ, UFS_VDDIQ2, UFS_VDDI, etc. of the uMCP297 may be also, but is not limited to be, led out on the circuit board 21000, and other signals such as UFS_DIN0_T, UFS_DIN0_C, UFS_DOUT1_T, UFS_DOUT1_C, etc. may be also led out to the first metal pad 21130 for later use.

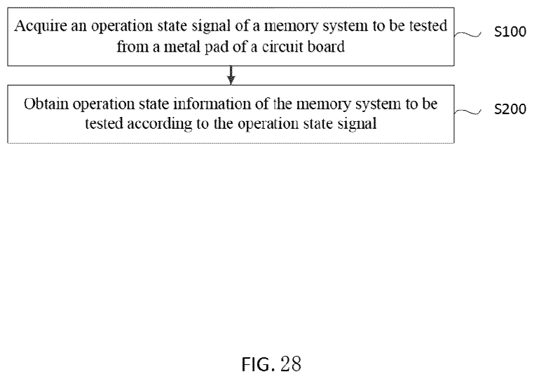

Based on the aforementioned circuit board or test system shown in FIGS. 9, 10, 11, 12, 13, 14, 15, 16, 17, 18, 19, 20, 21, 22, 23, 24, 25, 26, and 27, a test method including the following S100-S200 shown in FIG. 28 may be implemented.

At S100, an operation state signal of a memory system to be tested is acquired from a metal pad of a circuit board.

In some examples, the operation state signal may include, but is not limited to, a voltage signal and a current signal, or may also include other signals to be tested. By using a test apparatus such as a current detection apparatus, an oscilloscope apparatus, etc., when measuring the power consumption of the memory system to be tested, the voltage signal and the current signal of the memory system to be tested during operation may be measured, and then are multiplied to obtain a power consumption value. Measuring the power consumption of a memory system in a cellphone is illustrated as an example, selection of a host in a test system may be consistent with that of a host of the cellphone. Measuring the power consumption of the memory system in the cellphone may be, but is not limited to, testing the power consumption of the memory system under conditions of hibernation, rebooting, video/audio playing, data reading and writing (uploading and downloading), etc. of the cellphone. For example, between downloading a movie file and playing a video/audio file, there may be a large difference in power consumption for the memory system. The operation state signal is configured to indicate operation state information of the memory system to be tested, and an operation state may include a normal state or an abnormal state. The abnormal state may include situations such as overcurrent, overheating, etc.

In some examples, in the circuit board 21000 shown in FIGS. 26 and 27, FIG. 26 shows the second side of the dielectric layer 21100 of the circuit board 21000 of a UFS portion in a uMCP chip, the second side of the dielectric layer 21100 further includes at least one second metal pad 21140 disposed at the peripheries of the plurality of second metal contacts 21120, and the second metal pads 21140 are coupled with the plurality of second metal contacts 21120 through a second wiring in the dielectric layer 21100. FIG. 27 shows the first side of the dielectric layer 21100 of the circuit board 21000 of the UFS portion in the uMCP chip. In conjunction with the uMCP297 chip, power supply signal points of the UFS portion include VCC, VCCQ, and VCCQ2. Taking the VCCQ as an example, all VCCQ signal points of the second side of the dielectric layer 21100 are pulled out and jointly connected to the position of a second metal pad 21140-A (including metal holes), defined as VCCQ_Host, which is directly connected to a VCCQ signal on the host 22000, a second metal pad 21140-B is placed beside and is defined as VCCQ_Device, which is connected back to a first metal pad 21130-A of a power supply layer on the first side of the dielectric layer 21100 through vias, and the VCCQ of the power supply layer on the first side of the dielectric layer 21100 is coupled with a first metal pad 21130-B. Since there is no wiring connection (e.g., an open circuit) between the first metal pad 21130-A and the first metal pad 21130-B in the circuit board 21000, during actual power consumption measurement, the VCCQ_Device and the VCCQ_Host may be coupled according to the electronic apparatus, and it is powered by the host or may be also directly connected to an external power supply for use. Therefore, the requirements of the circuit board for different test scenarios can be met.

At S200, the operation state information of the memory system to be tested is obtained according to the operation state signal.

In some examples, when measuring the power consumption of the memory system to be tested, the voltage signal and current signal of the memory system to be tested during operation can be obtained according the measurement, and then are multiplied to obtain a power consumption value. The power consumption value is compared with a preset power consumption value (or a preset power consumption range), and the operation state of the memory system to be tested under specific operating conditions (hibernation, rebooting, video/audio playing, data reading and writing (uploading and downloading), etc.) is determined according to a comparison result. For example, if the power consumption value is greater than the preset power consumption value or exceeds the preset power consumption range, it is determined that the power consumption of the memory system is abnormal under this operating condition.

According to the circuit board, the test system, and the test method provided by the present application, taking the system-level device power consumption measurement on a uMCP chip as an example, there is no need to search various power supply signals one by one and modify the power supply circuit. In this implementation, a signal pin to be tested is directly led out to a dedicated metal pad through the circuit board via an internal route, so as to accurately capture and test corresponding signals. This method is particularly suitable for a high-speed signal device such as an LPDDR, as the solution of signal line extension is often difficult to ensure the integrity and accuracy of signals during high-speed signal transmission; while in the present solution, the shorter line introduced in the circuit board 21000 has little impact on the LPDDR, which may avoid such a problem and ensure the reliability of the test result. Compared with a customized device measurement solution, implementations of the present application have universal applicability and platform adaptability. Since the uMCP chip generally employs a standard package type, the circuit board designed based on this standard can easily adapt various uMCP chips, no additional customization is required for specific platforms, and thus the circuit board may be compatible with various scenarios. Therefore, the test solution is more flexible and convenient, and can meet requirements of different scenarios and platforms. Furthermore, it reduces the difficulty of building of a test environment, increases the success rate of modification, and reduces the risk of platform damage, such that the test process is safer and more reliable. Furthermore, the implementations of the present application also significantly simplify the building process of the test environment, increases the success rate of modification, and effectively reduces the risk of platform damage, such that the test process is safer and more reliable. As such, power consumption measurement is completed without affecting the system performance.

Examples of the present disclosure provide circuit boards, test systems, and test methods. Examples of the present disclosure employ the following technical solutions:

In a first aspect, examples of the present disclosure provide a circuit board including: a dielectric layer including at least one conductive via extending through the dielectric layer; a plurality of first metal contacts disposed on a first side of the dielectric layer, and a plurality of second metal contacts disposed on a second side of the dielectric layer, where at least one of the plurality of first metal contacts is coupled with the second metal contacts through the conductive via; and at least one first metal pad located on the first side of the dielectric layer and at peripheries of the plurality of first metal contacts, where the first metal pad is coupled with at least one first metal contact through a first wiring in the dielectric layer.

In some implementations, the circuit board further includes at least one second metal pad located on the second side of the dielectric layer and at peripheries of the plurality of second metal contacts, where the second metal pad is coupled with at least one second metal contact through a second wiring in the dielectric layer.

In some implementations, the at least one second metal pad is disconnected from the at least one first metal pad.

In some implementations, the at least one second metal pad is coupled with the at least one first metal pad.

In some implementations, the peripheries of the plurality of first metal contacts include a plurality of first metal pads disposed on a same side of the peripheries of the plurality of first metal contacts.

In some implementations, the peripheries of the plurality of first metal contacts include a plurality of first metal pads disposed on at least two sides of the peripheries of the plurality of first metal contacts respectively.

In some implementations, on the second side of the dielectric layer, the corresponding thickness of the dielectric layer provided with the plurality of second metal contacts is greater than the corresponding thickness of the dielectric layer not provided with the plurality of second metal contacts.

In a second aspect, examples of the present disclosure provide a test system including a host and a circuit board stacked and coupled sequentially. The circuit board includes: a dielectric layer including at least one conductive via extending through the dielectric layer; a plurality of first metal contacts disposed on a first side of the dielectric layer, and a plurality of second metal contacts disposed on a second side of the dielectric layer, where at least one of the plurality of first metal contacts is coupled with the second metal contacts through the conductive via; and at least one first metal pad located on the first side of the dielectric layer and at peripheries of the plurality of first metal contacts, where the first metal pad is coupled with at least one first metal contact through a first wiring in the dielectric layer. The plurality of first metal contacts are configured to be coupled with a memory system to be tested. The circuit board is coupled with the host through the plurality of second metal contacts.

In some implementations, the circuit board further includes at least one second metal pad located on the second side of the dielectric layer and at peripheries of the plurality of second metal contacts, where the second metal pad is coupled with at least one second metal contact through a second wiring in the dielectric layer.

In some implementations, the at least one second metal pad is disconnected from the at least one first metal pad.

In some implementations, the at least one second metal pad is coupled with the at least one first metal pad.

In some implementations, the peripheries of the plurality of first metal contacts include a plurality of first metal pads disposed on a same side of the peripheries of the plurality of first metal contacts.

In some implementations, the peripheries of the plurality of first metal contacts include a plurality of first metal pads disposed on at least two sides of the peripheries of the plurality of first metal contacts respectively.

In some implementations, the dielectric layer includes an extending portion extending towards any direction of a plane where the memory system is located, and the first metal pad is disposed at the extending portion.

In some implementations, on the second side of the dielectric layer, the corresponding thickness of the dielectric layer provided with the plurality of second metal contacts is greater than the corresponding thickness of the dielectric layer not provided with the plurality of second metal contacts.

In some implementations, the test system further includes an intermediate plate disposed between the host and the circuit board, where the circuit board, the intermediate plate and the host are stacked and coupled sequentially.

In a third aspect, examples of the present disclosure provide a test method applied to the test system. The test method includes: acquiring an operation state signal of a memory system to be tested from a metal pad of a circuit board, where the operation state signal is configured to indicate operation state information of the memory system to be tested; and obtaining the operation state information of the memory system to be tested, according to the operation state signal.

The above descriptions are merely some implementations of the present disclosure, and the protection scope of the present disclosure is not limited to those. Any variation or replacement that may be readily figured out by those skilled in the art within the technical scope disclosed by the present disclosure shall be encompassed within the protection scope of the present disclosure. Therefore, the scope of protection of the present disclosure should be defined by the scope of protection of the claims.

What is claimed is:

1. A circuit board, comprising:
a dielectric layer including at least one conductive via extending through the dielectric layer;
a plurality of first metal contacts disposed on a first side of the dielectric layer and a plurality of second metal contacts disposed on a second side of the dielectric layer, wherein at least one of the plurality of first metal contacts is coupled with the second metal contacts through the at least one conductive via; and
at least one first metal pad located on the first side of the dielectric layer and at peripheries of the plurality of first metal contacts, wherein the first metal pad is coupled with at least one of the plurality of first metal contacts through a first wiring in the dielectric layer.

2. The circuit board of claim 1, further including at least one second metal pad located on the second side of the dielectric layer and at peripheries of the plurality of second metal contacts, wherein the second metal pad is coupled with at least one of the plurality of second metal contacts through a second wiring in the dielectric layer.

3. The circuit board of claim 2, wherein the at least one second metal pad is disconnected from the at least one first metal pad.

4. The circuit board of claim 2, wherein the at least one second metal pad is coupled with the at least one first metal pad.

5. The circuit board of claim 1, wherein the peripheries of the plurality of first metal contacts include a plurality of first metal pads disposed on a same side of the peripheries of the plurality of first metal contacts.

6. The circuit board of claim 1, wherein the peripheries of the plurality of first metal contacts include a plurality of first metal pads disposed on at least two sides of the peripheries of the plurality of first metal contacts respectively.

7. The circuit board of claim 1, wherein the dielectric layer includes recesses located on the second side of the dielectric layer and at peripheries of the plurality of second metal contacts.

8. A test system, comprising a host and a circuit board stacked and coupled sequentially, wherein the circuit board comprises:
a dielectric layer including at least one conductive via extending through the dielectric layer; a plurality of first metal contacts disposed on a first side of the dielectric layer and a plurality of second metal contacts disposed on a second side of the dielectric layer, wherein at least one of the plurality of first metal contacts is coupled with the second metal contacts through the at least one conductive via; and
at least one first metal pad located on the first side of the dielectric layer and at peripheries of the plurality of first metal contacts, wherein the first metal pad is coupled with at least one of the plurality of first metal contacts through a first wiring in the dielectric layer, and the plurality of first metal contacts are configured to be coupled with a memory system to be tested,
wherein the circuit board is coupled with the host through the plurality of second metal contacts.

9. The test system of claim 8, further including at least one second metal pad located on the second side of the dielectric layer and at peripheries of the plurality of second metal contacts, wherein the second metal pad is coupled with at least one of the plurality of second metal contacts through a second wiring in the dielectric layer.

10. The test system of claim 9, wherein the at least one second metal pad is disconnected from the at least one first metal pad.

11. The test system of claim 9, wherein the at least one second metal pad is coupled with the at least one first metal pad.

12. The test system of claim 8, wherein the peripheries of the plurality of first metal contacts include a plurality of first metal pads disposed on a same side of the peripheries of the plurality of first metal contacts.

13. The test system of claim 8, wherein the peripheries of the plurality of first metal contacts include a plurality of first metal pads disposed on at least two sides of the peripheries of the plurality of first metal contacts respectively.

14. The test system of claim 8, wherein the dielectric layer includes an extending portion extending towards any direction of a plane where the memory system is located, and the first metal pad is disposed at the extending portion.

15. The test system of claim 8, wherein the dielectric layer includes recesses located on the second side of the dielectric layer and at peripheries of the plurality of second metal contacts.

16. The test system of claim 8, further including an intermediate plate disposed between the host and the circuit board, wherein the circuit board, the intermediate plate and the host are stacked and coupled sequentially.

17. The test system of claim 8, wherein the host is coupled to the memory system to be tested through the circuit board.

18. The test system of claim 17, wherein the memory system comprises one of a solid state drive (SSD), an universal flash storage (UFS), and an embedded multimedia card (eMMC).

19. The test system of claim 17, wherein a size of the circuit board is greater than or equal to a size of the memory system to be tested.

20. A test method, applied to a test system including a host and a circuit board stacked and coupled sequentially, wherein the circuit board comprises:
a dielectric layer including at least one conductive via extending through the dielectric layer; a plurality of first metal contacts disposed on a first side of the dielectric layer and a plurality of second metal contacts disposed on a second side of the dielectric layer, wherein at least one of the plurality of first metal contacts is coupled with the second metal contacts through the at least one conductive via; and
at least one first metal pad located on the first side of the dielectric layer and at peripheries of the plurality of first metal contacts, wherein the first metal pad is coupled with at least one of the plurality of first metal contacts through a first wiring in the dielectric layer, and the plurality of first metal contacts are configured to be coupled with a memory system to be tested,
wherein the circuit board is coupled with the host through the plurality of second metal contacts, and
wherein the test method includes:
acquiring an operation state signal of the memory system to be tested from a metal pad of the circuit board, wherein the operation state signal is configured to indicate operation state information of the memory system to be tested; and
obtaining the operation state information of the memory system to be tested, according to the operation state signal.
